(19) United States
(12) Patent Application Publication
(10) Pub. No.: US 2013/0162273 A1
(43) Pub. Date: Jun. 27, 2013

(54) TESTING DEVICE

(71) Applicants: Chih-Jen CHIN, Taipei (TW); Pei-Lun HUANG, Taipei (TW)

(72) Inventors: Chih-Jen CHIN, Taipei (TW); Pei-Lun HUANG, Taipei (TW)

(21) Appl. No.: 13/433,744

(22) Filed: Mar. 29, 2012

(30) Foreign Application Priority Data
Dec. 21, 2011 (TW) 100147794

(51) Int. Cl. G01R 31/00

(52) U.S. Cl. 324/750.01

(57) ABSTRACT

A testing device comprising a power unit, a storage unit, and a controlling unit is mentioned. The power unit is adapted to provide different voltages. The storage unit is adapted to store a power sequence table and a simulation signal generating table. The controlling unit couples with the power unit and the storage unit, wherein the controlling unit is adapted to provide power sequence controlling signals according to the power sequence table, and the power unit is adapted to provide the voltages to the unit under test according to the power sequence controlling signals. The controlling unit is adapted to provide a simulation signal to the unit under test according to the simulation signal generating table, and the controlling unit is adapted to receive state signals generated by the unit under test in response to the voltages and the simulation signal.

### CROSS-REFERENCE TO RELATED APPLICATIONS

This non-provisional application claims priority under 35 U.S.C. §119(a) on Patent Application No(s). 100147794 filed in Taiwan, R.O.C. on Dec. 21, 2011, the entire contents of which are hereby incorporated by reference.

### BACKGROUND

1. Technical Field

The disclosure relates to a testing device, and more particularly to a testing device for providing simulation signals.

2. Related Art

Generally, before the computer systems are sold out, the computer systems would be tested. For the computers having multiple layers and multiple modules, the tests for them will be performed after the assembling of the complete computer is accomplished.

As the volume of the computer is large and therefore, restricts the testing abilities of testing devices, thus the In-Circuit Testing (ICT) can not be performed for the complete computer. Accordingly, the testing apparatus merely can be used for implementing the electrical test for a single board. A power supplier is connected to a signal module directly, and the power supplied to the single module can be changed and adjusted by the power supplier. However, the method can not perform the electrical test on each of the above-mentioned modules.

In addition, by the testing method for a single board as mentioned above, the startup sequence of the power and the operation signal needed by the single module can not be controlled. Furthermore, in the case of not considering whether state of the unit under test (for example, a main-board) is allowed to be powered and having no protection procedure for incorrect power sequence, the power supplier can not precisely control the power supplied to the unit under test since the actual power is unstable. Accordingly, the potential damage probability of the element of the unit is increased and the production cost is also increased.

### SUMMARY

The disclosure provides a testing device adapted for a unit under test. The testing device comprises a power unit, a storage unit, and a controlling unit. The power unit is adapted to provide different voltages. The storage unit is adapted to store a power sequence table and a simulation signal generating table. The controlling unit couples with the power unit and the storage unit, wherein the controlling unit is adapted to provide power sequence controlling signals according to the power sequence table, and the power unit is adapted to provide the voltages to the unit under test according to the power sequence controlling signals. The controlling unit is adapted to provide a simulation signal to the unit under test according to the simulation signal generating table, and the controlling unit is adapted to receive state signals generated by the unit under test in response to the voltages and the simulation signal.

### BRIEF DESCRIPTION OF THE DRAWINGS

The present disclosure will become more fully understood from the detailed description given herein below for illustration only, and thus are not limitative of the present disclosure, and wherein:

FIG. 1 is a block diagram of the testing device of an embodiment according to the present disclosure; and

FIG. 2 is a block diagram of the testing device of another embodiment according to the present disclosure.

### DETAILED DESCRIPTION

According to the problems as mentioned, testing devices of some embodiments, is disclosed for powering the UUT (unit under test) according to an appropriate power sequence and providing a simulation signal according to the UUT. Accordingly, testing a single module of the computer before the computer is assembled is available and, thus the probability of damaging the elements in circuit of the computer is reduced and the convenience for testing is improved.

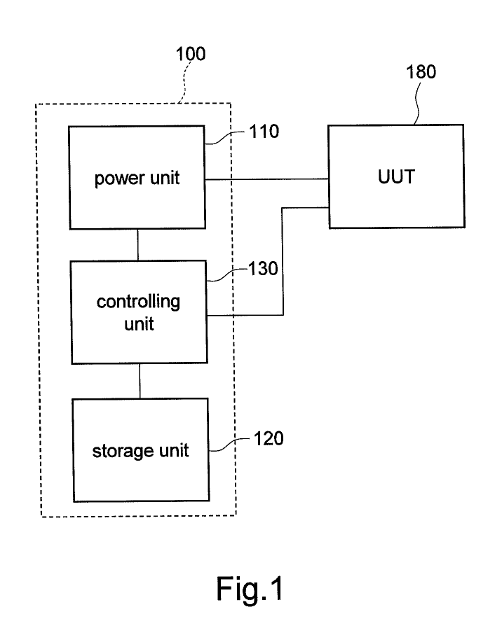

Refer to FIG. 1, wherein FIG. 1 is a block diagram of a structure of testing device according to an embodiment of the disclosure. According to the embodiment, the testing device 100 is adapted to test a UUT 180. For example, the UUT 180 may be a single board, such as a DIMM (Dual-Inline-Memory-Module), a CPU module, a Main I/O board and so on, and however the present disclosure is not limited to this embodiment.

The testing device 100 includes a power unit 110, a storage unit 120 and a controlling unit 130. The power unit 110 is used to different voltages, for example, 3.3V, 5V and 12V. However the present disclosure is not limited to the above example. The storage unit 120 is adopted to store a power sequence table and a simulation signal generating table both of which are corresponding to the UUT 180. For example, the power sequence of the UUT 180 from the starting operation to the regular operation may be recorded in the power sequence table, and the power good signal or the signals corresponding to the UUT 180 may be recorded in the simulation signal generating table.

Here, the controlling unit 130 couples to the power unit 110 and the storage unit 120 for providing multiple power sequence controlling signals to the power unit 110 according to the power sequence table. If the sequence of voltage outputting is 12V, 5V and 3.3V, the controlling unit 13 supplies the power sequence controlling signal with the sequence of 12V, 5V and 3.3V.

And then, according to the power sequence controlling signal, the power unit 110 supplies operating voltages to the UUT 180, so that the operations of the UUT 180 can be transferred from the starting operation to the regular operation. That is, according to the power sequence controlling signal mentioned above, the power unit 110 sequentially supplies the voltages 12V, 5V and 3.3V to the UUT 180, for ensuring that the UUT 180 could operates normally according to the appropriate power sequence.

In addition, according to the simulation signal generating table, the controlling unit 130 further provides simulation signals to the UUT 180. The simulation signals may be the power good signal in the previous stage or the signals provided from the other modules related to the UUT 180. For example, in the initial stage of the memory module, a confirm signal indicating the existence of the central processing unit is required. That is, when the

UUT 180 is a memory module, the controlling unit 130 can provide the confirm signal for simulating the existence of the central processing unit, so that the UUT 180 can processes the initial program.

In addition to the power sequence controlling signals and the simulation signal, the controlling unit 130 also can receive multiple state signals generated by the UUT 180, wherein the generation of the state signals is in respond to the voltages and the simulation signals provided by the power unit 110. For example, the state signals mentioned above may be a signal indicating a normal/abnormal power state, a signal indicating a normal/abnormal initial program state. In another word, after the UUT 180 receives a 12V voltage and is started, the signal indicating normal/abnormal state corresponding to the 12V voltage is sent back to the controlling unit 130; then when the UUT 180 receives a 5V voltage and is started, the signal indicating normal/abnormal state corresponding to the 5V voltage is sent back to the controlling unit 130; and the rest can be done in the same manner. Accordingly, in the present disclosure, the controlling unit 130 can be used to monitor the power sequence and the initial program of the UUT 180 and is be used to monitor the operations corresponding to the voltages and the simulation signal of the elements in the UUT 180.

Furthermore, for example, the controlling unit 130 may store the state signals mentioned above in the storage unit 120. Thus, the user can obtain the information from the storage unit 120, to confirm that if the UUT 180 is in the regular operation state, so as to perform further measurement(s) on the UUT 180 by the main testing device.

In this embodiment, the storage unit 120 and the controlling unit 130 can be implementing by CPLDs (Complex Programming Logic Devices).

In the embodiment, the testing device 100 provides the voltages and the simulation signals to the UUT 180, wherein the voltages and the simulation signal are corresponding to the power sequence required by the UUT 180. Therefore, even in the case that the UUT 180 is not assembled with other modules, the UUT 180 can still perform the power process and the initial process, just as if all the modules have been assembled, and thus the UUT 180 which is a single module (the memory module or the CPU module) can be tested. In this way, the potential probability of damaging the element can be reduced and the convenience for testing can be improved.

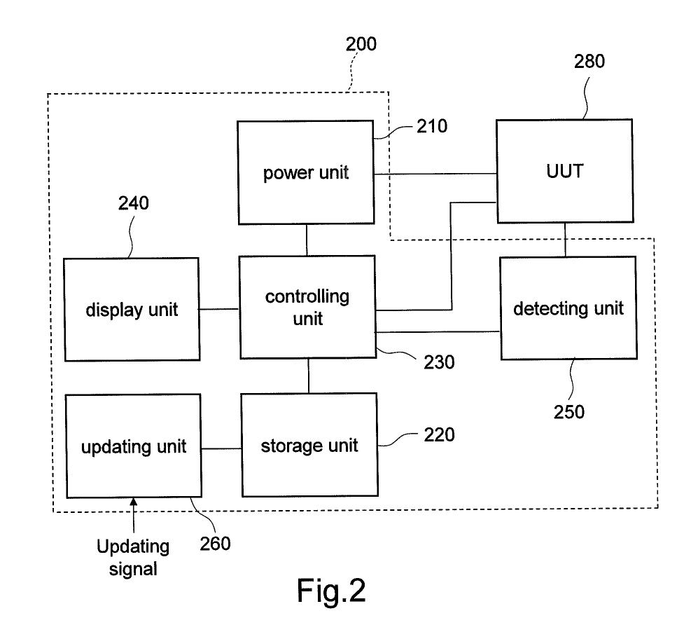

Refer to FIG. 2, wherein FIG. 2 is a block diagram of a structure of testing device according to another embodiment of the present disclosure. According to another embodiment, the testing device 200 is adapted to test a UUT 280. The testing device 200 includes a power unit 210, a storage unit 220, a controlling unit 230, a display unit 240, a detecting unit 250 and an updating unit 260.

The power unit 210 is used to supply different voltages, for example, 3.3V, 5V and 12V. The storage unit 220 is configured to store two power sequence tables and two simulation signal generating tables of the UUT 280. That is, the storage unit 220 may store two different power sequence tables and two different simulation signal generating tables required by two different types of UUTs 280. Both of the numbers of the power sequence tables and the number the simulation signal generating tables are 2, but the present disclosure is not limited to this embodiment. Therefore, in some embodiments, the user may adjust the number of the power sequence tables and the number of the simulation signal generating tables, according to the types of the UUTs 280.

The controlling unit 330 is coupled with the storage unit 220 and the power unit 210 and is used for providing the power sequence controlling signals and the simulation signals, according to one power sequence table and one simulation signal generating table or according to another power sequence table and another simulation signal generating table. And then, according to the power sequence controlling signals as mentioned above, the power unit 210 provides the voltages to UUT 280 sequentially. Furthermore, according to the simulation signal generating table, the controlling unit 230 provides the simulation signals required by the UUT 280. And then, the controlling unit 230 provides state signals, which are generated corresponding to the voltages and the simulation signals as mentioned above.

Then, display unit 240 couples with the controlling unit 230 for receiving the state signals sent back from the UUT 280 through the controlling unit 230 and displaying them. By this way, the user can learn whether the UUT 280 has errors by displaying the state on the displaying unit 240, so as to take the corresponding measures for the UUT 280.

The detecting unit 250 is coupled with the controlling unit 230 for detecting the type of the UUT 280, so that a detecting signal is generated. For example, the detecting unit 250 can be provided with connection ports having pins. In this way, when the detecting unit 250 is connected with the UUT 280 by the connection ports, the detecting unit 250 may detect the type of the UUT 280 based on the number and position of the pin connected with the connection ports. For example, the type of UUT may be a memory module or a CPU module. And then, the detecting unit 250 may generate the detecting signal and send it to the controlling unit 230.

Then, the controlling unit 230 selects one power sequence table and one simulation signal generating table or selects the other power sequence table and the other simulation signal generating table according to the detecting signal. As a result, the controlling unit 230 provides the corresponding power sequence signal and related the simulation signal. For example, the memory module is corresponding to the one power sequence table and the one simulation signal generating table, while the CPU module s corresponding to the other power sequence table and the other simulation signal generating table.

Furthermore, the updating unit 260 is coupled with the storage unit 220 for receiving and updating the power sequence table and the simulation signal generating table stored in the storage unit 220 according an updating signal. In other words, by using the updating unit 260, the user may update the version and number of the power sequence tables and the simulation signal generating tables stored in the storage unit 220. Accordingly, the convenience for testing can be improved. In this embodiment, the controlling unit 230 and the storage unit 220 can be implemented by complex programmable logic devices.

In the testing devices according to the embodiments of the present disclosure, after the testing device is connected to the UUT, the power sequence controlling signals corresponding to the power sequence are generated, and then the power sequence controlling signals are supplied to the UUT sequentially. Thus, the UUT is powered sequentially according to the appropriate power sequence, and the corresponding simulation signals are supplied to the UUT. By this way, the testing devices according to the embodiments can be used to test a single module, rather than a complete computer, and thus the probability of damaging the elements in the circuit of the computer is reduced. Furthermore, the testing device can display the state of the power sequence, for providing the voltage of power sequence and the simulation signal required by the UUT according to the type of the UUT, and updating the version and the number of the power sequence table, so as to improve the availability in the testing.

What is claimed is:

1. A testing device adapted for a unit under test, the testing device comprising:
a power unit for providing different voltages;
a storage unit for storing a power sequence table and a simulation signal generating table; and
a controlling unit coupled with the power unit and the storage unit, the controlling unit being adapted to provide power sequence controlling signals according to the power sequence table, the power unit being adapted to provide the voltages to the unit under test according to the power sequence controlling signals, the controlling unit being adapted to provide an simulation signal to the unit under test according to the simulation signal generating table, and the controlling unit being configured to receive state signals generated by the unit under test in response to the voltages and the simulation signal.

2. The testing device according to claim 1, further comprising:
an updating unit, coupled with the storage unit for receiving and updating the power sequence table and the simulation signal generating table stored in the storage unit according an updating signal.

3. The testing device according to claim 1, further comprising:
a display unit, coupled with the controlling for receiving the state signals through the controlling unit and displaying the state signals.

4. The testing device according to claim 1, wherein the storage unit is adapted to store another power sequence table and another simulation signal generating table for the unit under test, the testing device further comprises:
a detecting unit, for detecting the type of the unit under test, to generate a detecting signal,
wherein the controlling unit selects the power sequence table and the simulation signal generating table or selects the another power sequence table and the another simulation signal generating table according to the detecting signal, and then the controlling unit provides the power sequence signal and the simulation signal.

5. The testing device according to claim 1, wherein the controlling unit and the storage unit are provided in a complex programmable logic device.
